(19) United States
(12) Patent Application Publication
(10) Pub. No.: US 2017/0317639 A1
(43) Pub. Date: Nov. 2, 2017

(54) CIRCULATION TYPE SPACE-BASED SOLAR POWER SYSTEM

(71) Applicant: KOREA INSTITUTE OF ENERGY RESEARCH, Daejeon (KR)

(72) Inventors: Young-Joo EO, Daejeon (KR); Jun-Sik CHO, Daejeon (KR); Jae-ho YUN, Daejeon (KR); Sejin AHN, Daejeon (KR); Jihye GWAK, Daejeon (KR); Jin-su YOO, Daejeon (KR); Ara CHO, Daejeon (KR); Seoung-Kyu AHN, Daejeon (KR); Joo-Hyung PARK, Daejeon (KR); Kihwan KIM, Daejeon (KR)

(73) Assignee: KOREA INSTITUTE OF ENERGY RESEARCH, Daejeon (KR)

(21) Appl. No.: 15/293,421

(22) Filed: Oct. 14, 2016

(30) Foreign Application Priority Data
May 2, 2016 (KR) 10-2016-0054207

(51) Int. Cl. H02S 20/32; H02S 40/40; H01L 31/041; H02S 40/22; B64G 1/44; B64G 1/10

(52) U.S. Cl. CPC H02S 20/32; B64G 1/44; B64G 1/10; H01L 31/041; H02S 40/22; H02S 40/40

(57) ABSTRACT

Disclosed is a circulation type space-based solar power system, the system including: one or more solar modules; a conveyor belt on which the solar modules are attached, whereby the solar modules move between a solar power generating position and a recovery position, the solar modules receiving sunlight to generate solar power in the solar power generating position, and not receiving sunlight in the recovery position; a driver moving the conveyor belt; and a protective plate blocking cosmic rays incident to the solar modules located in the recovery position. The system can generate solar power for a long time by moving the solar modules between the solar power generating position and the recovery position. While some of the solar modules generate solar power, the remaining solar modules having damage are recovered.

### CROSS REFERENCE TO RELATED APPLICATION

The present application claims priority to Korean Patent Application No. 10-2016-0054207, filed May 2, 2016, the entire contents of which is incorporated herein for all purposes by this reference.

### BACKGROUND OF THE INVENTION

### Field of the Invention

The present invention relates generally to a circulation type space-based solar power system. More particularly, the present invention relates to a circulation type space-based solar power system able to be used in the severe environment of space by extending the life of solar modules as much as possible.

### Description of the Related Art

Generally, a solar power system having solar modules is used to obtain electricity in space, and is used, for example, for an artificial satellite.

However, unlike the Earth's surface that is protected by the atmosphere of the Earth, space is a severe environment due to temperature variation, cosmic rays, etc. Therefore, performance of solar modules rapidly is degraded in space, and consequently, the life of an entire solar power generation system is shortened.

In order to solve the problem, a conventional technology whereby solar power is generated by exposing a part of solar modules in stages, each time the performance of the exposed part is degraded, thereby supplementing a reduced amount of the solar power caused by the degraded performance, has been developed (Korean Patent Application Publication No. 10-2001-0077700). In addition, another conventional technology whereby spent movable solar modules are replaced with new movable solar modules by being moved, has been developed (Japanese Patent Application Publication No. Hei. 11-157499).

However, the conventional technologies are based on that the fact that the lives of the solar modules will be terminated in the end, and thus the life of the entire solar power generation system remains short.

### Documents of Related Art

(Patent Document 1) Korean Patent Application Publication No. 10-2001-0077700, and

(Patent Document 2) Japanese Patent Application Publication No. Hei. 11-157499.

### SUMMARY OF THE INVENTION

Accordingly, the present invention has been made keeping in mind the above problems occurring in the related art, and the present invention is intended to propose a circulation type space-based solar power system, the system having extended life in the severe environment of space by recovering the solar modules for recycling thereof.

In order to achieve the above object, according to one aspect of the present invention, there is provided a circulation type space-based solar power system, the system including: one or more solar modules; a conveyor belt on which the solar modules are attached, whereby the solar modules move between a solar power generating position and a recovery position, the solar modules receiving sunlight to generate solar power in the solar power generating position, and not receiving the sunlight in the recovery position; a driver moving the conveyor belt; and a protective plate blocking cosmic rays incident to the solar modules located in the recovery position.

In the system, the solar modules generate solar power in the solar power generating position, and the solar modules having damage are recovered in the recovery position. The solar modules move between the solar power generating position and the recovery position by the conveyor belt and the driver. The moving of the solar modules may be performed at preset time intervals, or when an amount of the solar power generated by the solar modules located in the solar power generating position is equal to or less than a preset reference amount. In addition, in space, even the solar modules that do not face the Sun are continuously damaged by the cosmic rays. Therefore, the solar modules are protected by the protective plate blocking the cosmic rays in the recovery position. With the configuration, while some of the solar modules generate solar power in the solar power generation position, the remaining solar modules having damage are recovered in the recovery position protected by the protective plate blocking the cosmic rays. The solar modules move between the solar power generating position and the recovery position, thereby generating solar power for a long time in the severe environment of space.

Here, the system may include a reflective plate increasing an amount of the sunlight incident to the solar modules located in the solar power generating position. In addition, the system may include a temperature control device controlling a temperature of the solar modules located in the recovery position, thereby enhancing the recovery effect of the solar modules.

The system may be applied to an artificial satellite. In this case, the conveyor belt is provided on a paddle of the artificial satellite.

According to another aspect, there is provided a circulation type space-based solar power system, the system including: one or more solar modules; a body having at least two module attaching surfaces on which the solar modules are attached; a turning device whereby the module attaching surfaces loaded with the solar modules move between a solar power generating position and a recovery position by turning of the body, the solar modules of the module attaching surfaces receiving sunlight to generate solar power in the solar power generating position, and not receiving sunlight in the recovery position; and an openable protective plate provided on each of the module attaching surfaces, wherein when the openable protective plate is closed, cosmic rays incident to the solar modules located in the recovery position are blocked by the openable protective plate, and when the openable protective plate is opened, the sunlight is incident to the solar modules located in the solar power generating position.

In the system, the solar modules of the module attaching surfaces of the body generate solar power in the solar power generating position, and the damaged solar modules of the module attaching surfaces of the body are recovered in the recovery position. The module attaching surfaces loaded with the solar modules move between the solar power generating position and the recovery position by the turning device turning the body. The moving of the module attaching surfaces loaded with the solar modules may be performed at preset time intervals, or when an amount of the solar power generated by the solar modules located in the solar power generating position is equal to or less than a preset reference amount. In addition, with the configuration, while some of the solar modules generate solar power in the solar power generation position, the remaining solar modules having damage are recovered in the recovery position protected by the openable protective plate blocking the cosmic rays. Since the protective plate provided with the body moves with the module attaching surfaces, the protective plate is of a type that can be opened and closed.

Here, a reflective surface may be provided on an inner surface of the openable protective plate such that it is possible to increase an amount of the sunlight incident to the solar modules located in the solar power generation position. The system may include a temperature control device controlling a temperature of the solar modules located in the recovery position.

In addition, the openable protective plate may be opened and closed by using a shape-memory alloy.

In addition, a cross-sectional shape of the body may be a triangular or a quadrilateral shape such that the module attaching surfaces of the body are three or four surfaces. In this case, one of the module attaching surfaces facing the Sun is located in the solar power generating position, and the remaining module attaching surfaces are located in the recovery position.

The system may be applied to an artificial satellite. In this case, the body is a paddle of the artificial satellite, and the turning device turns the paddle.

According to yet still another aspect, there is provided a circulation type space-based solar power system, the system including: one or more solar modules; a turning device whereby the solar modules move between a solar power generating position and a recovery position, the solar modules receiving sunlight to generate solar power in the solar power generating position, and not receiving the sunlight in the recovery position; and a protective plate blocking cosmic rays incident to the solar modules located in the recovery position.

A method of generating solar power in space by using the system includes: positioning some of the solar modules in the solar power generating position where the solar modules receive sunlight and generate solar power, and positioning the remaining solar modules in the recovery position where the solar modules having damage do not receive sunlight so as to be recovered; and moving the solar modules between the solar power generating position and the recovery position.

Here, the moving of the solar modules may be performed at preset time intervals, or when an amount of the solar power generated by the solar modules located in the solar power generating position is equal to or less than a preset reference amount.

According to the described above, the system and method can recover the solar modules having damage in the recovery position by using the protective plate blocking the cosmic rays in the recovery position in which the solar modules do not receive the sunlight, and can generate solar power by using the recovered solar modules in the solar power generating position.

In addition, the system and method can generate solar power for a long time in the severe environment of space by moving the solar modules between the solar power generating position and the recovery position. While some of the solar modules generate solar power in the solar power generating position, the remaining solar modules having damage are recovered in the recovery position protected by the protective plate blocking cosmic rays.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a view showing a circulation type space-based solar power system according to a first exemplary embodiment of the present invention; and

FIG. 2 is a view showing a circulation type space-based solar power system according to a second exemplary embodiment of the present invention.

### DETAILED DESCRIPTION OF THE INVENTION

Hereinbelow, exemplary embodiments of the present invention will be described in detail with reference to the accompanying drawings.

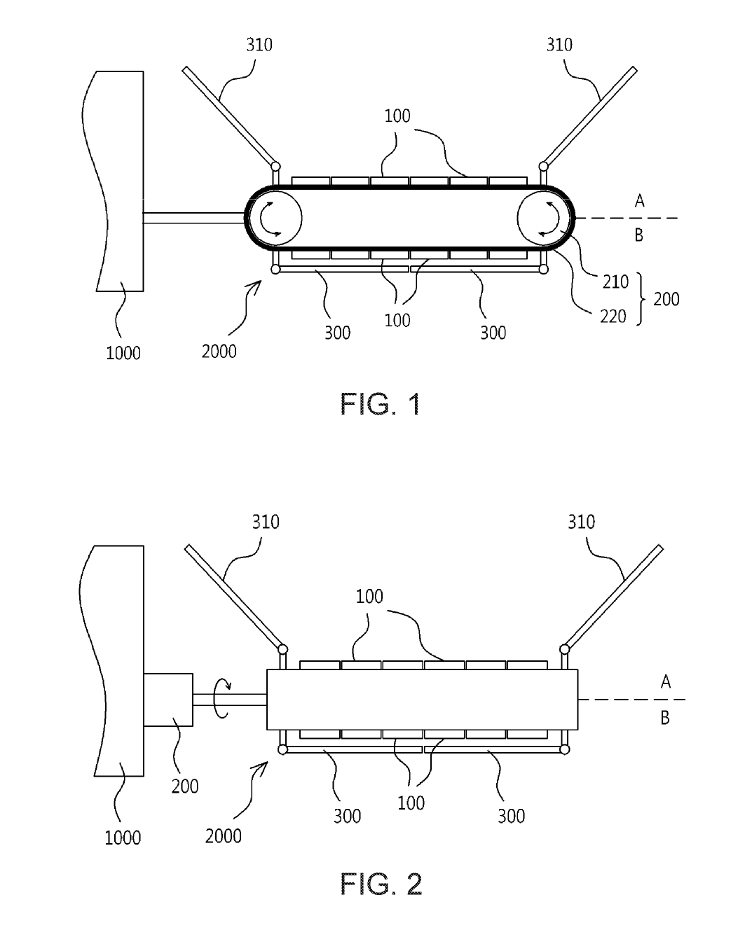

FIG. 1 is a view showing a circulation type space-based solar power system according to a first exemplary embodiment of the present invention.

According to a first exemplary embodiment as shown in the figure, the system is applied to an artificial satellite, and is provided on a solar power generating paddle 2000 connected to an artificial satellite body 1000.

The system includes a plurality of solar modules 100, and a conveyor belt 220 moved by a driver 210. The conveyor belt serves as a turning device 200 moving the solar modules 100.

The solar modules 100 are attached on the conveyor belt 220, and are moved by the driver 210 moving the conveyor belt 220. Here, the solar modules 100 move between the front and rear positions denoted as A and B in FIG. 1. The front position, denoted as A, faces the Sun, and the rear position, denoted as B, faces the opposite direction of the Sun. The solar modules located in A generate solar power by receiving sunlight. The solar modules located in B do not generate solar power. However, the solar modules located in B are not just in an idle state. The solar modules located in B, are protected from cosmic rays, etc. by a protective plate 300 preventing the solar modules in B from being exposed to the severe environment of space. Therefore, performances of solar cells of the solar modules are recovered. Accordingly, the front position, denoted as A, is a solar power generating position, and the rear position, denoted as B, is a recovery position. By the moving of the conveyor belt 220, the solar modules located in the solar power generating position A move to the recovery position B, while the solar modules located in the recovery position B move to the solar power generating position A. According to the space-based solar power system of the first exemplary embodiment, the solar modules move between the solar power generating position A and the recovery position B.

Here, in the protective plate 300 protecting the solar modules in the recovery position B, it is desirable to include a temperature control device maintaining a suitable temperature for recovering the solar cells of the solar modules. In addition, it is desirable to provide a reflective plate 310 for supplying more sunlight to the solar modules located in the solar power generating position A.

A method of operating the space-based solar power system is by generating solar power in the solar power generating position A by using the solar modules that are degraded by being exposed to the severe environment of space, up to the time when the solar modules are capable of being recovered. The solar modules are moved to the recovery position B by the turning device, before sustain irreparable damage. Here, the solar modules recovered in the recovery position B move to the solar power generating position A, and generate solar power, thereby continuously generating solar power. The solar modules move between the solar power generating position A for generating solar power and the recovery position B for recovery. Therefore, it is possible to generate solar power for a long time in the severe environment of space.

Here, a degree of the damage to the solar modules, which is a criterion for moving the solar modules, varies depending on the type of the solar cells of the solar modules. The moving of the solar modules is performed at preset time intervals based on the type of the solar cells, or performed based on a degree of decrease in the amount of solar power, the decrease being caused by damage to the solar modules.

FIG. 2 is a view showing a space-based solar power system according to a second exemplary embodiment of the present invention.

According to the second exemplary, the system is applied to the artificial satellite, and is provided on the solar power generating paddle 2000 connected to the artificial satellite body 1000.

The system uses the solar power generating paddle 2000 as a body. Module attaching surfaces on which the solar modules 100 are attached are respectively provided on upper and lower surfaces of the body. The module attaching surfaces loaded with the solar modules move between the solar power generating position, denoted as A, and the recovery position, denoted as B, by the turning device 200 turning the paddle.

In common with the system of the first exemplary embodiment, the system of the second exemplary embodiment also includes the protective plate 300 protecting the solar modules located in the recovery position B from the cosmic rays, etc. However, unlike the system of the first exemplary embodiment, the paddle 2000 itself is turned, such that the protective plate 300 also moves between the solar power generating position A and the recovery position B. Therefore the protective plate 300 is an openable protective plate. The openable protective plate 300 is closed and protects the solar modules in the recovery position B, and the openable protective plate 300 is opened and allows the sunlight to incident to the solar modules in the solar power generating position A. Here, the openable protective plate 300 may be opened and closed by using a shape-memory alloy. The openable protective plate 300 may be opened and closed by using a temperature difference between the solar power generating position A and the recovery position B. In addition, when a reflective surface 310 is provided on an inner surface of the openable protective plate 300, the openable protective plate 300 opened in the solar power generating position A serves as a reflective plate.

FIG. 2 shows the paddle 2000 having two module attaching surfaces that are the upper and lower surfaces. However, the paddle may have three or four module attaching surfaces. In this case, one of the module attaching surfaces facing the Sun is located in the solar power generating position, and the remaining module attaching surfaces are located in the recovery position. When moving the three or four module attaching surfaces loaded with the solar modules, the time for the recovery in the recovery position is extended.

While the exemplary embodiments of the invention have been described above, the embodiments are only examples of the invention, and it will be understood by those skilled in the art that the invention can be modified in various forms without departing from the technical spirit of the invention. Therefore, the scope of the invention should be determined on the basis of the descriptions in the appended claims, not any specific embodiment, and all equivalents thereof should belong to the scope of the invention.

What is claimed is:

1. A circulation type space-based solar power system, the system comprising:
one or more solar modules;
a conveyor belt on which the solar modules are attached, whereby the solar modules move between a solar power generating position and a recovery position, the solar modules receiving sunlight to generate solar power in the solar power generating position, and not receiving the sunlight in the recovery position;
a driver moving the conveyor belt; and
a protective plate blocking cosmic rays incident to the solar modules located in the recovery position.

2. The system of claim 1, further comprising:
a reflective plate increasing an amount of the sunlight incident to the solar modules located in the solar power generating position.

3. The system of claim 1, further comprising:
a temperature control device controlling a temperature of the solar modules located in the recovery position.

4. The system of claim 1, wherein the system is applied to an artificial satellite, and the conveyor belt is provided on a paddle of the artificial satellite.

5. The system of claim 1, wherein the solar modules move between the solar power generating position and the recovery position at preset time intervals, or when an amount of the solar power generated by the solar modules located in the solar power generating position is equal to or less than a preset reference amount.

6. A circulation type space-based solar power system, the system comprising:
one or more solar modules;
a body having at least two module attaching surfaces on which the solar modules are attached;
a turning device whereby the module attaching surfaces loaded with the solar modules move between a solar power generating position and a recovery position by turning of the body, the solar modules of the module attaching surfaces receiving sunlight to generate solar power in the solar power generating position, and not receiving the sunlight in the recovery position; and
an openable protective plate provided on each of the module attaching surfaces,
wherein when the openable protective plate is closed, cosmic rays incident to the solar modules located in the recovery position are blocked by the openable protective plate, and when the openable protective plate is opened, the sunlight is incident to the solar modules located in the solar power generating position.

7. The system of claim 6, wherein a reflective surface is provided on an inner surface of the openable protective plate.

8. The system of claim 6, wherein the openable protective plate is opened and closed by using a shape-memory alloy.

9. The system of claim 6, further comprising:
a temperature control device controlling a temperature of the solar modules located in the recovery position.

10. The system of claim 6, wherein a cross-sectional shape of the body is a triangular or a quadrilateral shape such that the module attaching surfaces of the body are three or four surfaces, and
one of the module attaching surfaces facing the Sun is located in the solar power generating position, and the remaining module attaching surfaces are located in the recovery position.

11. The system of claim 6, wherein the system is applied to an artificial satellite, and the body is a paddle of the artificial satellite.

12. The system of claim 6, wherein the module attaching surfaces loaded with the solar modules move between the solar power generating position and the recovery position at preset time intervals, or when an amount of the solar power generated by the solar modules located in the solar power generating position is equal to or less than a preset reference amount.

13. A method of generating solar power in space by using the system of claim 1, the method comprising:
positioning some of the solar modules in the solar power generating position where the solar modules receive sunlight and generate solar power, and positioning the remaining solar modules in the recovery position where the solar modules having damage do not receive sunlight so as to be recovered; and
moving the solar modules between the solar power generating position and the recovery position,
wherein the moving of the solar modules is performed at preset time intervals, or when an amount of the solar power generated by the solar modules located in the solar power generating position is equal to or less than a preset reference amount.
